(19) United States
(12) Patent Application Publication
(10) Pub. No.: US 2015/0024142 A1
(43) Pub. Date: Jan. 22, 2015

(54) MAGNETIC RECORDING MEDIUM AND METHOD FOR PRODUCING PROTECTIVE FILM THEREOF

(71) Applicant: FUJI ELECTRIC (MALAYSIA) SDN, BHD., Kedah Darul Aman (MY)

(72) Inventor: Naruhisa NAGATA, Matsumoto-city (JP)

(21) Appl. No.: 14/508,424

(22) Filed: Oct. 7, 2014

Related U.S. Application Data
(63) Continuation of application No. PCT/MY2012/000266, filed on Oct. 29, 2012.

(51) Int. Cl. G11B 5/84; C23C 16/27; C23C 16/50

(52) U.S. Cl. CPC G11B 5/8408; C23C 16/50; C23C 16/276
USPC 427/535

(57) ABSTRACT

A method for producing a protective film for a magnetic recording medium comprises steps of (a) providing a magnetic layer formed on a substrate; and (b) forming a protective film on the magnetic layer by means of a plasma CVD method using mixed gas of specific lower saturated hydrocarbon gas and specific lower unsaturated hydrocarbon gas as source gas. Step (b) includes (b-1) of forming a first protective film on the magnetic layer and (b-2) of forming a second protective film on the first protective film. B-1 uses source gas with gas mixture ratio such that average number of hydrogen atoms per carbon atom in the source gas is greater than 2.5 but less than 3.0. B-2 uses source gas with gas mixture ratio such that the average number of hydrogen atoms per carbon atom in the source gas is greater than 2.0 but less than 2.5.

### BACKGROUND OF THE INVENTION

A. Field of the Invention

The present disclosure relates to a method for producing a magnetic recording medium and a protective film that is suitable for producing a magnetic recording medium.

B. Description of the Related Art

In order to improve the recording density of a hard disk drive (HDD), not only is it necessary to improve its magnetic recording layer, but also the distance between the magnetic recording layer and a magnetic head for reading/writing information (magnetic spacing) needs to be reduced. Therefore, technologies have been used which reduce the thickness of a protective film formed on the magnetic recording layer, reduce the thickness of a lubricating film formed on the protective film, or reduce the flying height of the magnetic head. Technology known as a flying on demand (FOD), which causes a read/write element part of the magnetic head to protrude to reduce the effective flying height, has been used.

Among all these technologies, reducing the thickness of the protective film in the magnetic recording medium is quite important. Japanese Patent Application Publication No. 2010-205323 proposes a technology for reducing the thickness of a protective film.

### SUMMARY OF THE INVENTION

However, the recent protective films need to be reduced in thickness and be able to further adapt to the FOD and other technologies by improving the bonding with lubricating layers.

The present invention provides a magnetic recording medium capable of further realizing the reduction in thickness of a protective film and further adapting to the FOD and other technologies without undermining the reliability, such as corrosion resistance and durability, of the magnetic recording medium.

The invention of the present application provides a method for producing a protective film, which can be used for producing a magnetic recording medium having a substrate, a magnetic layer formed on the substrate, a protective film formed on the magnetic layer, and a lubricating layer formed on the protective film, the method having the steps of:

(a) providing the magnetic layer formed on the substrate; and

(b) forming the protective film on the magnetic layer by means of a plasma CVD method using mixed gas of lower saturated hydrocarbon gas and lower unsaturated hydrocarbon gas as source gas,

wherein the lower saturated hydrocarbon gas is selected from the group consisting of methane, ethane, propane, butane, and a mixture of two or more thereof,

the lower unsaturated hydrocarbon gas is selected from the group consisting of ethylene, propylene, butylene, butadiene, and a mixture of two or more thereof, and

the step (b) includes a step (b-1) of forming a first protective film on the magnetic layer and a step (b-2) of forming a second protective film on the first protective film,

the step (b-1) being performed by the plasma CVD method using a source gas in which a mixture ratio between the lower saturated hydrocarbon gas and the lower unsaturated hydrocarbon gas is adjusted such that the average number of hydrogen atoms per carbon atom in the source gas becomes greater than 2.5 but less than 3.0, and

the step (b-2) being performed by the plasma CVD method using a source gas in which a mixture ratio between the lower saturated hydrocarbon gas and the lower unsaturated hydrocarbon gas is adjusted such that the average number of hydrogen atoms per carbon atom in the source gas becomes greater than 2.0 but less than 2.5.

### DETAILED DESCRIPTION OF SPECIFIC EMBODIMENTS

a. Method for Producing a Protective Film, which can be Used for Producing a Magnetic Recording Medium

The method for producing a protective film according to the invention of the present application, which can be used for producing a magnetic recording medium, has the steps of:

(a) providing the magnetic layer formed on the substrate; and

(b) forming the protective film on the magnetic layer by means of a plasma CVD method using mixed gas of lower saturated hydrocarbon gas and lower unsaturated hydrocarbon gas as source gas.

### (1) Step (a)

The magnetic layer on which the protective film is formed is provided by the step (a).

(1-1)

The magnetic layer is formed on the substrate. The substrate is preferably non-magnetic and can be made of any material that has conventionally been used in producing a magnetic recording medium. The substrate can be made of, for example, a Ni—P plated aluminum alloy, glass, ceramic, plastic, or silicon.

(1-2)

The magnetic layer is formed by stacking metallic film layers on the substrate and includes at least a magnetic recording layer.

The magnetic recording layer can be formed using a ferromagnetic material such as an alloy containing at least Co and Pt. It is desired that an easy axis of magnetization of the ferromagnetic material be oriented in a direction of performing magnetic recording. For instance, when performing perpendicular magnetic recording, the easy axis of magnetization [a c-axis with a hexagonal closest packing (hcp) structure] of a material of the magnetic recording layer needs to be oriented in a direction perpendicular to a surface of the recording medium (i.e., perpendicular to a principle plane of the substrate).

It is further preferred that the magnetic recording layer be a perpendicular magnetic recording layer consisting of a single layer or multiple layers, which is formed using a material with a granular structure having magnetic crystal grains dispersed in a non-magnetic oxide matrix or a non-magnetic nitride matrix. Examples of the material with a granular structure that can be used here include CoPt—SiO₂, CoCrPtO, CoCrPt—SiO₂, CoCrPt—TiO₂, CoCrPt—Al₂O₃, CoPt—AlN, and CoCrPt—Si₃N₄, but are not limited thereto. In the invention of the present application, the use of the material with a granular structure is preferred in terms of promoting magnetic separation between the magnetic crystal grains that are adjacent to each other in the perpendicular magnetic recording layer, reducing noise, and improving the characteristics of the medium such as its SNR and recording resolution.

Note that the magnetic recording layer can be formed using any method known in the technology, such as a sputtering method (a DC magnetron sputtering method, RF magnetron sputtering method, etc.) or a vacuum evaporation method.

(1-3)

The magnetic layer mentioned in (1-2) above may optionally include a non-magnetic underlayer, a soft magnetic layer, a seed layer, an intermediate layer, and other layers between the magnetic recording layer and the substrate. These layers may be magnetic or non-magnetic layers.

Non-Magnetic Underlayer

The non-magnetic underlayer can be formed using a non-magnetic material including Cr such as Ti or a CrTi alloy.

Soft Magnetic Layer

The soft magnetic layer can be formed using a crystalline material such as FeTaC or Sendust (FeSiAl) alloy; a microcrystalline material such as FeTaC, CoFeNi, or CoNiP; or an amorphous material that includes a Co alloy such as CoZrNd, CoZrNb, or CoTaZr. The soft magnetic layer functions to concentrate a perpendicular magnetic field generated by the magnetic head, in a magnetic recording layer of a perpendicular magnetic recording medium. Although the optimal value of the film thickness of the soft magnetic layer changes depending on the structure or characteristics of the magnetic head used for recording, it is preferred that the film thickness of the soft magnetic layer be approximately 10 nm to 500 nm in order to balance with the productivity.

Seed Layer

The seed layer can be formed using a permalloy material such as NiFeAl, NiFeSi, NiFeNb, NiFeB, NiFeNbB, NiFeMo, or NiFeCr; a material obtained by adding Co to a permalloy material, such as CoNiFe, CoNiFeSi, CoNiFeB, or CoNiFeNb; Co; or a Co-base alloy such as CoB, CoSi, CoNi, or CoFe. It is preferred that the seed layer be thick enough to control the crystalline structure of the magnetic recording layer and normally have a film thickness of at least 3 nm but no more than 50 nm.

Intermediate Layer

The intermediate layer can be formed using Ru or an alloy that mainly contains Ru. It is preferred that the intermediate layer normally have a film thickness of at least 0.1 nm but no more than 20 nm. The film thickness in this range can provide the magnetic recording layer with the characteristics required to achieve high density recording, without degrading the magnetic properties or magnetic recording properties of the magnetic recording layer.

Note that, as with the magnetic recording layer, the non-magnetic underlayer, the soft magnetic layer, the seed layer, and the intermediate layer can be formed using any method known in the technology, such as a sputtering method (a DC magnetron sputtering method, RF magnetron sputtering method, etc.) or a vacuum evaporation method.

### (2) Step (b)

In the step (b), the protective film is formed on the magnetic layer provided by the step (a).

(2-1)

The protective film is formed using a plasma chemical vapor deposition (CVD) method using hydrocarbon gas as the source gas. In this method, the source gas is put in a plasma state and caused to generate active radicals or ions, thereby forming an amorphous carbon thin film as the protective film. It is preferred that the amorphous carbon be diamond-like carbon (DLC), in terms of providing surface smoothness and hardness.

Power for generating plasma may be supplied using a capacitively-coupled method or an inductively coupled method. The power to be supplied can be DC power, HF power (frequency: several tens to several hundreds kHz), RF power (frequency: 13.56 MHz, 27.12 MHz, 40.68 MHz, etc.), a microwave (frequency: 2.45 GHz), or the like.

A parallel plate type apparatus, filament type apparatus, ECR plasma generator, helicon wave plasma generator, or the like can be used as an apparatus for generating plasma. In the invention of the present application, a filament type plasma CVD apparatus is preferably used.

(2-2)

Mixed gas of lower saturated hydrocarbon gas and lower unsaturated hydrocarbon gas is used as the source gas. Generally, while the film formation speed of the lower saturated hydrocarbon gas is relatively low, the film formation speed of the lower unsaturated hydrocarbon gas is relatively high. The film formation speed can be controlled by using the mixed gas and adjusting the mixture ratio between the lower saturated hydrocarbon gas and the lower unsaturated hydrocarbon gas.

The lower saturated hydrocarbon gas is selected from the group consisting of methane, ethane, propane, butane, and a mixture of two or more thereof. The lower unsaturated hydrocarbon gas is selected from the group consisting of ethylene, propylene, butylene, butadiene, and a mixture of two or more thereof.

Above all, it is preferred that ethane be used as the lower saturated hydrocarbon gas and ethylene as the lower unsaturated hydrocarbon gas, due to their excellent corrosion resistance.

Note that other hydrocarbon gas such as acetylene or benzene may be included in an amount of less than 10 mol % without undermining the effects of the present invention.

(2-3)

The step (b) includes the step (b-1) of forming the first protective film on the magnetic layer and the step (b-2) of forming the second protective film on the first protective film. In these steps (b-1) and (b-2), the mixture ratio of the mixed gas (the mixture ratio between the lower saturated hydrocarbon gas and the lower unsaturated hydrocarbon gas), which is the source gas to be used, is changed.

Specifically, the step (b-1) is performed by the plasma CVD method using the source gas in which the mixture ratio between the lower saturated hydrocarbon gas and the lower unsaturated hydrocarbon gas is adjusted such that the average number of hydrogen atoms per carbon atom in the source gas becomes greater than 2.5 but less than 3.0.

The step (b-2) is performed by the plasma CVD method using the source gas in which the mixture ratio between the lower saturated hydrocarbon gas and the lower unsaturated hydrocarbon gas is adjusted such that the average number of hydrogen atoms per carbon atom in the source gas becomes greater than 2.0 but less than 2.5.

The average number of hydrogen atoms N per carbon atom in the source gas can be calculated using the following formula where NHi represents the number of hydrogen atoms in a molecule of each hydrocarbon gas i, NCi represents the number of carbon atoms in a molecule of each hydrocarbon gas i, and Fi represents the flow rate (sccm) of each the hydrocarbon gas:

N=Σ(N_{H}ⁱ×Fⁱ)/Σ(N_{C}ⁱ×Fⁱ).

In this formula, Σ denotes the sum of each hydrocarbon gas i.

In the step (b-1), the source gas having the mixture ratio in which the average number of hydrogen atoms per carbon atom is relatively high is used, so that more of the tetrahedral structure resulting from C—H bonding is introduced into the obtained first protective film, improving the corrosion resistance/durability of the magnetic recording medium.

In the step (b-2), on the other hand, the use of the source gas having the mixture ratio in which the average number of hydrogen atoms per carbon atom is relatively low, can reduce the amount of hydrogen (H) component in the obtained second protective film that interferes with the bonding between the lubricating layer and the protective film, improving the FOD performance.

In the step (b-1), the average number of hydrogen atoms per carbon atom in the source gas is set to be greater than 2.5, based on the technical aspect of introducing more of the tetrahedral structure resulting from C—H bonding. Moreover, the average number of hydrogen atoms per carbon atom in the source gas is set to be less than 3.0, based on the technical aspect of preventing polymerization that results from excess hydrogen.

In the step (b-2), on the other hand, the average number of hydrogen atoms per carbon atom in the source gas is set to be greater than 2.0, based on the technical aspect of maintaining the tetrahedral structure resulting from C—H bonding. Moreover, the average number of hydrogen atoms per carbon atom in the source gas is set to be less than 2.5, based on the technical aspect of reducing the amount of hydrogen that interferes with the bonding between the protective film and the lubricating layer.

(2-4)

The properties of the first and second protective films described in (2-3) above can favorably be controlled by further adjusting the potential difference for ion acceleration in the plasma CVD method. In other words, more of the tetrahedral structure resulting from C—H bonding can be introduced into the protective film by setting the potential difference for ion acceleration relatively low, and the amount of hydrogen (H) component accumulating in the protective film to be formed can be reduced by setting the potential difference for ion acceleration relatively high.

More specifically, a preferred upper limit of the potential difference for ion acceleration adjusted by the plasma CVD method in the step (b-1) is equal to or lower than 180 V in terms of introducing more of the tetrahedral structure resulting from C—H bonding, and a preferred lower limit of the potential difference for ion acceleration is equal to or greater than 60 V in terms of maintaining plasma discharge. On the other hand, a preferred lower limit of the potential difference for ion acceleration adjusted by the plasma CVD method in the step (b-2) is equal to or greater than 180 V in terms of reducing the amount of hydrogen that interferes with the bonding with the lubricating layer, and a preferred upper limit of the potential difference for ion acceleration is equal to or lower than 300 V in terms of maintaining the tetrahedral structure resulting from C—H bonding.

Here, the potential difference for ion acceleration is calculated by the following formula (I):

Potential difference for ion acceleration=Anode potential−Bias potential (1)

The anode potential is a potential applied to an anode in the plasma CVD apparatus. The bias potential is a potential in the plasma CVD apparatus applied to the magnetic layer formed on the substrate, which is provided by the step (a). For example, when the anode potential=+60 V and the bias potential=−120 V, the potential difference for ion acceleration=anode potential−bias potential=(+60 V)−(−120 V)=180 V.

(2-5)

The film thickness of the protective film is preferably equal to or greater than 1.2 nm in terms of realizing excellent corrosion resistance, and is preferably equal to or lower than 2.5 nm in terms of reducing magnetic spacing loss with respect to the magnetic head and realizing excellent magnetic recording properties.

In addition, the protective film of the present invention includes the first protective film and the second protective film, wherein the ratio between the film thickness of the first protective film and the film thickness of the second protective film is preferably 3:7 to 7:3 in terms of effectively exerting excellent corrosion resistance/durability of the first protective film and excellent FOD performance of the second protective film.

### (3) Step (c)

Step (c) may include a step of further nitriding a surface of the protective film obtained in the step (b).

This step can introduce a nitrogen (N) component for facilitating the bonding between the surface of the protective film and the lubricating layer, further improving the FOD performance.

Introducing the nitrogen (N) component can be performed by introducing nitrogen gas into, for example, a plasma source and subjecting a surface of a carbon layer to nitrogen plasma processing.

### B. Method for Producing a Magnetic Recording Medium

Subsequent to “A. Method for producing a protective film,” which is described above, a magnetic recording medium can be produced by forming the lubricating layer on the protective film. The resultant magnetic recording medium has at least a substrate, a magnetic layer formed on the substrate, a protective film formed on the magnetic layer, and a lubricating layer formed on the protective film.

The lubricating layer is a layer for providing lubricity between the magnetic head and the magnetic recording medium. The lubricating layer can be formed on the substrate by using a liquid lubricant known in the technical field. Specifically, it is preferred to use perfluoropolyether liquid lubricant (PFPE). The liquid lubricant can be applied to the lubricant layer to a thickness of approximately 1 nm by means of a dip coating method or spin coating method. Specific examples of the liquid lubricant include Fomblin-Z-tetraol (manufactured by Solvay Solexis) and A20H (manufactured by MORESCO).

It is preferred that the layer thickness of the lubricant layer be equal to or greater than 0.7 nm in terms of realizing excellent durability and equal to or lower than 1.8 nm in terms of reducing magnetic spacing loss with respect to the magnetic head and realizing excellent magnetic recording properties.

### EXAMPLES

### Example 1

### (1) Providing a Substrate Having a Magnetic Layer

First, a substrate with a magnetic layer was prepared using a circular aluminum disc with an outer diameter of 95 mm, inner diameter of 25 mm, and thickness of 1.27 mm according to the following procedure.

Namely, first, a surface of the aluminum disc was coated with Ni—P to a film thickness of 12 μm to prepare a non-magnetic substrate. The obtained non-magnetic substrate was smoothed and cleansed.

Next, using a DC magnetron sputtering method, a plurality of metallic films (non-magnetic underlayer, soft magnetic layer, seed layer, intermediate layer, first magnetic layer, exchange coupling control layer, second magnetic layer, and third magnetic layer) were formed sequentially on the cleansed non-magnetic substrate. Specifically:
A Cr50Ti50 film was stacked on the non-magnetic substrate to form a non-magnetic underlayer with a film thickness of 6.0 nm;
A CoZrNb film was stacked on the non-magnetic underlayer to form a soft magnetic layer with a film thickness of 20 nm;
A CoNiFe film was stacked on the soft magnetic layer to form a seed layer with a film thickness of 8.0 nm;
Ru was stacked on the seed layer to form an intermediate layer with a film thickness of 10 nm;
A CoCrPt—SiO₂ film was stacked on the intermediate layer to form a first magnetic layer with a film thickness of 10 nm;
A Ru film was stacked on the first magnetic layer to form a exchange coupling control layer with a film thickness of 0.2 nm;
A CoCrPt—SiO₂ film was stacked on the exchange coupling control layer to form a second magnetic layer with a film thickness of 3.0 nm; and
A CoCrPt—B film was stacked on the second magnetic layer to form a third magnetic layer with a film thickness of 6.0 nm.

Note that the magnetic recording layer on the substrate has a four-layer structure of the first magnetic layer, exchange coupling control layer, second magnetic layer, and third magnetic layer.

### (2) Forming a Protective Film

Next, a protective film was formed on the resultant magnetic layer by using a plasma CVD method. Using a filament type plasma CVD apparatus, a predetermined current was supplied to a cathode filament to emit thermoelectrons, and at the same time hydrocarbon gas serving as the source gas was introduced into the apparatus to generate hydrocarbon gas plasma.

Mixed gas of ethane (C₂H₆) gas and ethylene (C₂H₄) gas was used as the source gas. In a first step, the flow rate of the ethane (C₂H₆) gas was set at 45 sccm, the flow rate of the ethylene (C₂H₄) gas at 15 sccm, the anode potential at +40 V, the bias potential at −60 V (i.e., the potential difference for ion acceleration was 100 V), and the temperature of the substrate at approximately 180° C. Film formation time was adjusted, and the first protective film (DLC film) with a thickness of 1.0 nm was formed on the magnetic layer. In other words, the average number of hydrogen atoms per carbon atom in the source gas was 2.75 in the first step.

Subsequently, in a second step, the flow rate of the ethylene (C₂H₄) gas was set at 45 sccm, the flow rate of the ethane (C₂H₆) gas at 15 sccm, the anode potential at +80 V, and the bias potential at −180 V (i.e., the potential difference for ion acceleration was 260 V). The film formation time was adjusted, and the second protective film (DLC film) with a thickness of 1.0 nm was formed on the first protective film. In other words, the average number of hydrogen atoms per carbon atom in the source gas was 2.25 in the second step.

The first and second protective films were combined into a protective film (DLC film) with a thickness of 2.0 nm.

Furthermore, in a third step, the flow rate of nitrogen (N₂) gas was set at 50 sccm, the temperature of the substrate at approximately 180° C., and processing time at 1.0 second, to nitride a surface of the second protective film.

The unit “sccm” used herein indicates the flow rate per minute (unit: cm³) in a standard condition (1 atm/0° C.).

### (3) Forming a Lubricating Layer

A liquid lubricant that mainly contains perfluoropolyether (HOCH₂CH(OH)CH₂—OCH₂CF₂O—(CF₂CF₂O)n—(CF₂O)m—CF₂CH₂O—CH₂CH(OH)CH₂OH, with a molecular weight of 2000 to 4000) was applied to the protective film obtained in the manner described above by using a dip method to form a lubricating layer with a thickness of 1.0 nm.

### (4) Evaluation of Corrosion Resistance

Nitric acid aqueous solution of a predetermined concentration (3.0%) in an amount 0.5 mL was dropped on four sections at 90° intervals in the magnetic recording medium sample that was prepared according to (1) to (3) described above and extracted to measure the amount of Co elution by means of inductively coupled plasma mass spectroscopy (ICP-MS). A calibration curve of a standard sample was used when measuring the amount of Co elution.

The amount of Co elution was as low as 0.019 ng/cm², which was a good result.

The amount of Co elution equal to or lower than 0.040 ng/cm² was evaluated as “particularly” good and set as a reference criterion. Under this value, the magnetic recording medium does not cause any problems when evaluating its reliability in the HDD.

### (5) Evaluation of Durability

An AlTiC ball with a diameter of 2 mm was slid along the magnetic recording medium sample prepared according to (1) to (3) described above, with a load of 30 gf and at a linear velocity of 25 cm/s, to measure how many times the AlTiC ball needs to be slid until the protective film breaks. It took 470 times to break the protective film, which was a good result.

The number of times that the AlTiC ball was slid that is equal to or greater than 400 was evaluated as “particularly” good and set as a reference criterion. Over this value, the magnetic recording medium does not cause any problems when evaluating its reliability in the HDD.

### (6) Evaluation of FOD Performance

When the magnetic head was flown at a predetermined rotation speed, a heater embedded in the read/write element part of the magnetic head was switched on to thermally expand the read/write element part of the magnetic head and to gradually protrude the read/write element part. Then, touch-down (TD) heater power was measured at which the flying magnetic head goes unstable. The TD was detected using an acoustic emission (AE) sensor at a rotation speed of 7200 rpm. The TD heater power was as large as 50.7 mW, which was a good result.

The TD heater power equal to or greater than 50.0 mW was evaluated as “particularly” good and set as a reference criterion. This value indicates the level at which the effect of FOD can be seen in the magnetic recording properties of the magnetic recording medium.

### Examples 2 to 9

A magnetic recording media were prepared using the same method as Example 1, on condition that the mixture ratio between ethane (C₂H₆) gas and ethylene (C₂H₄) gas used in the first formation step of a protective film was changed variously. The other conditions are the same as those of Example 1. In other words, the substrate, magnetic layer, second protective film, and lubricating layer are the same in Examples 1 to 9.

The results of evaluations of corrosion resistance and durability of these magnetic recording media are shown in Table 1 along with the evaluation results obtained in Example 1.

TABLE 1
The flow rates of the source gas in the first
step and the results of evaluations of corrosion
resistance/durability of the example magnetic recording media

| | Source gas | | | | |
|---|---|---|---|---|---|
| | | | Average | | |
| | | | number | | |
| | | | hydrogen | | |
| | | Ethylene | atoms per | Evaluation of | |
| | Ethane gas | gas flow | carbon | corrosion | Evaluation of |
| | flow rate | rate | atom | resistance | durability |
| Example 1 | 45 sccm | 15 sccm | 2.75 | 0.019 ng/cm² | 470 times |
| Example 2 | 45 sccm | 30 sccm | 2.60 | 0.020 ng/cm² | 460 times |
| Example 3 | 45 sccm | 45 sccm | 2.50 | 0.041 ng/cm² | 330 times |
| Example 4 | 30 sccm | 15 sccm | 2.67 | 0.023 ng/cm² | 440 times |
| Example 5 | 30 sccm | 30 sccm | 2.50 | 0.042 ng/cm² | 320 times |
| Example 6 | 30 sccm | 45 sccm | 2.40 | 0.048 ng/cm² | 290 times |
| Example 7 | 15 sccm | 15 sccm | 2.50 | 0.045 ng/cm² | 300 times |
| Example 8 | 15 sccm | 30 sccm | 2.33 | 0.050 ng/cm² | 270 times |
| Example 9 | 15 sccm | 45 sccm | 2.25 | 0.063 ng/cm² | 240 times |

As is clear from the evaluation results shown in Table 1 above, when the flow rate of the ethane (C₂H₆) gas was greater than the flow rate of ethylene (C₂H₄) gas and the average number of hydrogen atoms per carbon atom in the source gas was greater than 2.5 but less than 3.0, excellent corrosion resistance (equal to or lower than 0.040 ng/cm²) and durability (equal to or greater than 400 times of sliding) were obtained (Examples 1, 2, 4).

However, when the flow rate of the ethane (C₂H₆) gas was lower than the flow rate of the ethylene (C₂H₄) gas and the average number of hydrogen atoms per carbon atom in the source gas was greater than 2.0 but equal to or lower than 2.5, the corrosion resistance and durability became worse (Examples 3, 5 to 9).

### Examples 10 to 17

The condition in which the mixture ratio between ethylene (C₂H₄) gas and ethane (C₂H₆) gas used in the second formation step of a protective film was changed variously was implemented using the same method as Example 1. The other conditions are the same as those of Example 1. In other words, the substrate, magnetic layer, first protective film, and lubricating layer are the same in Examples 1 and 10 to 17.

The results of the FOD performance of these magnetic recording media are shown in Table 2 along with the results obtained in Example 1.

TABLE 2
The flow rates of the source gas in the
second step and the results of evaluations of the
FOD performance of the example magnetic recording media

| | Source gas | | | |
|---|---|---|---|---|
| | | | Average | |
| | | | number of | |
| | | | hydrogen | Evaluation |
| | Ethane gas | Ethylene | atoms per | of FOD |
| | flow rate | gas flow rate | carbon atom | performance |
| Example 1 | 15 sccm | 45 sccm | 2.25 | 50.7 mW |
| Example 10 | 15 sccm | 30 sccm | 2.33 | 50.4 mW |
| Example 11 | 15 sccm | 15 sccm | 2.50 | 49.5 mW |
| Example 12 | 30 sccm | 45 sccm | 2.40 | 50.1 mW |
| Example 13 | 30 sccm | 30 sccm | 2.50 | 49.0 mW |
| Example 14 | 30 sccm | 15 sccm | 2.67 | 48.6 mW |
| Example 15 | 45 sccm | 45 sccm | 2.50 | 48.7 mW |
| Example 16 | 45 sccm | 30 sccm | 2.60 | 47.9 mW |
| Example 17 | 45 sccm | 15 sccm | 2.75 | 46.8 mW |

As is clear from the evaluation results shown in Table 2 above, when the flow rate of the ethylene (C₂H₄) gas was greater than the flow rate of the ethane (C₂H₆) gas and the average number of hydrogen atoms per carbon atom in the source gas was greater than 2.0 but less than 2.5, excellent FOD performance (equal to or greater than 50.0 mW) were obtained (Examples 1, 10, 12).

However, when the flow rate of the ethylene (C₂H₄) gas was lower than the flow rate of the ethane (C₂H₆) gas and the average number of hydrogen atoms per carbon atom in the source gas was equal to or greater than 2.5 but less than 3.0, the FOD performance became worse (Examples 11, 13 to 17).

### Examples 18 to 25

The condition in which the potential difference for ion acceleration (=anode potential−bias potential) of the first formation step of a protective film was changed variously was implemented using the same method as Example 1. The other conditions are the same as those of Example 1. In other words, the substrate, magnetic layer, second protective film, and lubricating layer are the same in Examples 1 and 18 to 25.

The results of evaluations of the corrosion resistance and durability of these magnetic recording media are shown in Table 3 along with the results obtained in Example 1.

TABLE 3
The Potential difference for ion acceleration in the
first step and the results of evaluations of the corrosion
resistance/durability of the example magnetic recording media

| | | | Potential | Evaluation | |
|---|---|---|---|---|---|
| | | | difference | of | Evaluation |
| | Anode | Bias | for ion | corrosion | of |
| | potential | potential | acceleration | resistance | durability |
| Example 1 | +40 V | −60 V | 100 V | 0.019 ng/cm² | 470 times |
| Example 18 | +40 V | −120 V | 160 V | 0.032 ng/cm² | 410 times |
| Example 19 | +40 V | −180 V | 220 V | 0.056 ng/cm² | 290 times |
| Example 20 | +60 V | −60 V | 120 V | 0.020 ng/cm² | 470 times |
| Example 21 | +60 V | −120 V | 180 V | 0.038 ng/cm² | 400 times |
| Example 22 | +60 V | −180 V | 240 V | 0.067 ng/cm² | 230 times |
| Example 23 | +80 V | −60 V | 140 V | 0.022 ng/cm² | 460 times |
| Example 24 | +80 V | −120 V | 200 V | 0.044 ng/cm² | 340 times |
| Example 25 | +80 V | −180 V | 260 V | 0.075 ng/cm² | 200 times |

As is clear from the evaluation results shown in Table 3, the potential difference for ion acceleration (=anode potential−bias potential) that was equal to or lower than 180 V resulted in excellent corrosion resistance (equal to or lower than 0.040 ng/cm²) and excellent durability (equal to or greater than 400 times of sliding on the magnetic recording medium sample) (Examples 1, 18, 20, 21, 23).

### Examples 26 to 33

The condition in which the potential difference for ion acceleration (=anode potential−bias potential) of the second formation step of a protective film was changed variously was implemented using the same method as Example 1. The other conditions are the same as those of Example 1. In other words, the substrate, magnetic layer, first protective film, and lubricating layer are the same in Examples 1 and 26 to 33.

The results of the FOD performance of these magnetic recording media are shown in Table 4 along with the results obtained in Example 1.

TABLE 4
The Potential difference for ion acceleration in the
second step and the results of evaluations of the FOD
performance of the example magnetic recording media

| | | | Potential | Evaluation |
|---|---|---|---|---|
| | Anode | | difference for ion | of FOD |
| | potential | Bias potential | acceleration | performance |
| Example 1 | +80 V | −180 V | 260 V | 50.7 mW |
| Example 26 | +80 V | −120 V | 200 V | 50.2 mW |
| Example 27 | +80 V | −60 V | 140 V | 48.8 mW |
| Example 28 | +60 V | −180 V | 240 V | 50.6 mW |
| Example 29 | +60 V | −120 V | 180 V | 50.0 mW |
| Example 30 | +60 V | −60 V | 120 V | 48.1 mW |
| Example 31 | +40 V | −180 V | 220 V | 50.4 mW |
| Example 32 | +40 V | −120 V | 160 V | 49.4 mW |
| Example 33 | +40 V | −60 V | 100 V | 47.5 mW |

As is clear from the results shown in Table 4, the potential difference for ion acceleration (=anode potential−bias potential) that was equal to or greater than 180 V resulted in excellent FOD performance (equal to or greater than 50.0 mW) (Examples 1, 26, 28, 29, 31).

Thus, a method for producing a magnetic recording medium and a protective film that is suitable for producing a magnetic recording medium have been described according to the present invention. Many modifications and variations may be made to the techniques and structures described and illustrated herein without departing from the spirit and scope of the invention. Accordingly, it should be understood that the methods and films described herein are illustrative only and are not limiting upon the scope of the invention.

What is claimed is:

1. A method for producing a protective film for a magnetic recording medium having a substrate, a magnetic layer formed on the substrate, a protective film formed on the magnetic layer, and a lubricating layer formed on the protective film, the method comprising the steps of:
(a) providing a substrate with a magnetic layer thereon; and
(b) forming the protective film on the magnetic layer by means of a plasma CVD method using a mixed gas of a lower saturated hydrocarbon gas and a lower unsaturated hydrocarbon gas as a source gas,
wherein the lower saturated hydrocarbon gas is selected from the group consisting of methane, ethane, propane, butane, and a mixture of two or more thereof,
the lower unsaturated hydrocarbon gas is selected from the group consisting of ethylene, propylene, butylene, butadiene, and a mixture of two or more thereof, and
the step (b) includes a step (b-1) of forming a first protective film on the magnetic layer and a step (b-2) of forming a second protective film on the first protective film,
the step (b-1) being performed by the plasma CVD method using a source gas in which a mixture ratio between the lower saturated hydrocarbon gas and the lower unsaturated hydrocarbon gas is adjusted such that the average number of hydrogen atoms per carbon atom in the source gas becomes greater than 2.5 but less than 3.0, and
the step (b-2) being performed by the plasma CVD method using a source gas in which a mixture ratio between the lower saturated hydrocarbon gas and the lower unsaturated hydrocarbon gas is adjusted such that the average number of hydrogen atoms per carbon atom in the source gas becomes greater than 2.0 but less than 2.5.

2. The method for producing a protective film according to claim 1, wherein the lower saturated hydrocarbon gas is ethane and the lower unsaturated hydrocarbon gas is ethylene.

3. The method for producing a protective film according to claim 1, wherein a potential difference for ion acceleration applied by the plasma CVD method in the step (b-1) is equal to or lower than 180 V, and a potential difference for ion acceleration applied by the plasma CVD method in the step (b-2) is equal to or greater than 180 V.

4. The method for producing a protective film according to claim 1, further comprising, subsequent to the step (b), a step (c) of nitriding a surface of the protective film.

5. A method for producing a magnetic recording medium comprising the steps of:
providing a substrate;
forming a magnetic layer on the substrate; and
forming a protective film on the magnetic layer by means of a plasma CVD method using a mixed gas of a lower saturated hydrocarbon gas and a lower unsaturated hydrocarbon gas as a source gas,
wherein the lower saturated hydrocarbon gas is selected from the group consisting of methane, ethane, propane, butane, and a mixture of two or more thereof,
the lower unsaturated hydrocarbon gas is selected from the group consisting of ethylene, propylene, butylene, butadiene, and a mixture of two or more thereof, and
the step (b) includes a step (b-1) of forming a first protective film on the magnetic layer and a step (b-2) of forming a second protective film on the first protective film,
the step (b-1) being performed by the plasma CVD method using a source gas in which a mixture ratio between the lower saturated hydrocarbon gas and the lower unsaturated hydrocarbon gas is adjusted such that the average number of hydrogen atoms per carbon atom in the source gas becomes greater than 2.5 but less than 3.0, and
the step (b-2) being performed by the plasma CVD method using a source gas in which a mixture ratio between the lower saturated hydrocarbon gas and the lower unsaturated hydrocarbon gas is adjusted such that the average number of hydrogen atoms per carbon atom in the source gas becomes greater than 2.0 but less than 2.5.

6. The method according to claim 5, additionally comprising a step of forming a lubricating layer on the protective film.

7. The method according to claim 5, wherein the lower saturated hydrocarbon gas is ethane and the lower unsaturated hydrocarbon gas is ethylene.

8. The method according to claim 5, wherein a potential difference for ion acceleration applied by the plasma CVD method in the step (b-1) is equal to or lower than 180 V, and a potential difference for ion acceleration applied by the plasma CVD method in the step (b-2) is equal to or greater than 180 V.

9. The method according to claim 5, further comprising, subsequent to the step (b), a step (c) of nitriding a surface of the protective film.
